(19) United States
(12) Patent Application Publication
(10) Pub. No.: US 2026/0215141 A1
(43) Pub. Date: Jul. 23, 2026

(54) DISPLAY PANEL

(71) Applicant: LG Display Co., Ltd., Seoul (KR)

(72) Inventors: Min Gue SHIN, Paju-si (KR); Seung Kwang ROH, Paju-si (KR); Woo Chul CHOI, Paju-si (KR); Sang Kyoung MOON, Paju-si (KR); Dong ll CHOI, Paju-si (KR); Jung Mo CHO, Paju-si (KR); Chi Hak LEE, Paju-si (KR); Bo A JIN, Paju-si (KR)

(21) Appl. No.: 19/441,793

(22) Filed: Jan. 6, 2026

(30) Foreign Application Priority Data
Jan. 23, 2025 (KR) 10-2025-0010313

(51) Int. Cl. H10K 59/80; H10K 59/122

(52) U.S. Cl. CPC H10K 59/8792; H10K 59/122; H10K 59/879

(57) ABSTRACT

A display panel includes a first subpixel including a first light emitting device emitting first color light, a second subpixel including a second light emitting device emitting second color light, a first color filter lens including a first lens disposed to overlap on the first subpixel and a first color filter layer disposed on a surface of the first lens, and a second color filter lens including a second lens disposed to overlap on the second subpixel and a second color filter layer disposed on a surface of the second lens, in which the first color filter layer includes a pigment transmitting the first color light, the second color filter layer includes a pigment transmitting the second color light, and a transmittance of the second color light of the second color filter layer is lower than a transmittance of the first color light of the first color filter layer.

### CROSS REFERENCE TO RELATED APPLICATION

This application claims priority from and the benefit of Korean Patent Application No. 10-2025-0010313, filed on Jan. 23, 2025, which is hereby incorporated by reference for all purposes as if fully set forth herein.

### BACKGROUND

### Field

Embodiments of the invention relate to a display panel.

### Discussion of the Background

As information technology advances, the market for display apparatuses which are connection mediums connecting a user with information is increasing. Therefore, the use of display apparatuses such as light emitting display apparatuses, quantum dot display (QDD) apparatuses, and liquid crystal display (LCD) apparatuses is increasing.

Recently, as display apparatuses described above are used in vehicles, various technologies such as a light control film in panel (LIP), where a lens or a light control film (LCF) using a louver is embedded in a panel, are being used for preventing light of a display apparatus from obstructing a field of view of a driver.

In an LIP structure, lenses are respectively disposed on subpixels emitting lights of different colors, and lights emitted from the subpixels may be respectively collected through the lenses, and thus, luminance may increase.

However, when lights of different colors pass through lenses, a per-color luminance ratio variation differs with respect to a viewing angle, and due to this, there is a problem where visibility varies with respect to the same viewing angle in the same color coordinates, causing a problem where color coordinates should be re-set.

The above information disclosed in this Background section is only for understanding of the background of the inventive concepts, and, therefore, it may contain information that does not constitute prior art.

### SUMMARY

Embodiments of the invention may provide a display panel which may decrease a per-color luminance variation with respect to a viewing angle, in a structure where a lens is provided on a subpixel.

Additional features of the inventive concepts will be set forth in the description which follows, and in part will be apparent from the description, or may be learned by practice of the inventive concepts.

According to embodiments of the invention, a display panel includes a first subpixel including a first light emitting device emitting first color light, a second subpixel including a second light emitting device emitting second color light, a first color filter lens including a first lens disposed to at least partially overlap on the first subpixel and a first color filter layer disposed on a surface of the first lens, and a second color filter lens including a second lens disposed to at least partially overlap on the second subpixel and a second color filter layer disposed on a surface of the second lens, in which the first color filter layer includes a pigment transmitting the first color light, the second color filter layer includes a pigment transmitting the second color light, and a transmittance of the second color light of the second color filter layer is lower than a transmittance of the first color light of the first color filter layer.

The first color filter layer and the second color filter layer may include a first pigment in common.

A reduction rate of brightness of the second color light caused by the first pigment may be greater than a reduction rate of brightness of the first color light caused by the first pigment.

Each of the first and second lenses may include a lens material including at least one of a polymer-based material and an inorganic material, without being limited to, and each of the first and second color filter layers may include a combination of the first pigment and the lens material.

The first pigment may include at least one of green color filter pigment and blue color filter pigment, and the green color filter pigment may be selected from at least one of chlorinated copper phthalocyanine (PG7), PG36, and nickel complex pigments, and the blue color filter pigment may be selected from at least one of copper phthalocyanine (PB15:3), indanthrone blue (PB60), and ultramarine blue.

An outer surface of each of the first and second color filter layers may include a curved surface corresponding to an upper curved surface of a corresponding lens among the first and second lenses.

A refractive index of the first color filter layer may be substantially the same as a refractive index of the first lens, and a refractive index of the second color filter layer may be substantially the same as a refractive index of the second lens.

A maximum height of each of the first and second lenses may be greater than a maximum width of each of the first and second lenses.

A thickness of each of the first and second color filter layers at a side surface of a corresponding lens among the first and second lenses may be greater than a thickness of each of the first and second color filter layers at a center of an upper surface of a corresponding lens among the first and second lenses.

A brightness reduction rate of the second color light caused by the second color filter layer may be greater at a second viewing angle than at a first viewing angle corresponding to a front of the second light emitting device, the second viewing angle being different from the first viewing angle.

The first color light may be red light, and the second color light may be green light or blue light.

Only one first color filter lens may be disposed on the first subpixel, and only one second color filter lens may be disposed on the second subpixel.

The display panel may further include an encapsulation layer disposed on the first and second light emitting devices, an optical layer disposed between the encapsulation layer and the first and second color filter lenses, and a low refractive layer disposed on the first and second color filter lenses, wherein a refractive index of each of the first and second color filter lenses may be greater than a refractive index of the low refractive layer.

A thickness of the optical layer may be less than a maximum height of each of the first and second color filter lenses.

A thickness of the low refractive layer may be greater than a maximum height of each of the first and second color filter lenses.

The display panel may further include a bank defining an emission region of the first subpixel and an emission region of the second subpixel, wherein the bank may at least partially overlap a space between the first color filter lens and the second color filter lens.

The display panel may further include a first barrier at a portion at least partially overlapping the bank, between the encapsulation layer and the optical layer, wherein the first barrier may be a black matrix including a light-absorbing material.

The display panel may further include a second barrier at a portion at least partially overlapping the bank, between the optical layer and the low refractive layer, wherein the second barrier may be a touch electrode of a metal material.

The display panel may further include a third subpixel including a third light emitting device emitting third color light, a third color filter lens including a third lens disposed to at least partially overlap on the third subpixel and a third color filter layer disposed on a surface of the third lens, in which the third color filter layer may include a pigment transmitting the third color light, and a transmittance of the third color light of the third color filter layer is lower than a transmittance of the first color light of the first color filter layer.

Brightness reduction rate of the third color light caused by the third color filter layer may be greater at a second viewing angle than at a first viewing angle corresponding to a front of the third light emitting device, the second viewing angle being different from the first viewing angle.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a configuration diagram for describing a concept of a configuration of a display apparatus according to an embodiment of the invention.

FIG. 2 is a circuit diagram for describing a pixel equivalent circuit applicable to a display panel according to an embodiment of the invention.

FIG. 3 is a cross-sectional view describing a structure of a display panel according to an embodiment of the invention.

FIG. 4 is a diagram for describing functions of first to third color filter layers illustrated in FIG. 3.

FIG. 5 is an enlarged view describing a thickness variation of a color filter layer in each color filter lens illustrated in FIG. 3.

FIGS. 6A and 6B are graphs describing a degree to which brightness of second and third color lights is reduced with respect to a viewing angle, when a color filter layer has a thickness as in FIG. 5.

FIG. 7 is a graph describing brightness variations of first to third color lights R, G, and B with respect to a viewing angle when a lens disposed on a subpixel is configured with only a transparent lens without a color filter layer.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a display apparatus according to an embodiment of the present disclosure will be described with reference to the accompanying drawings.

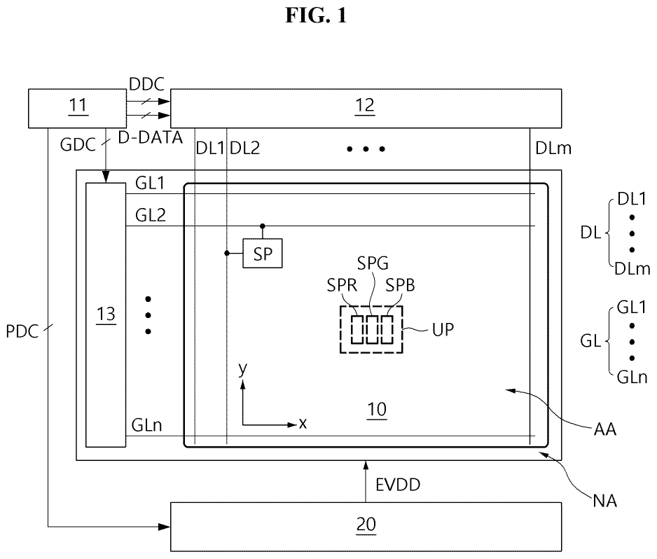

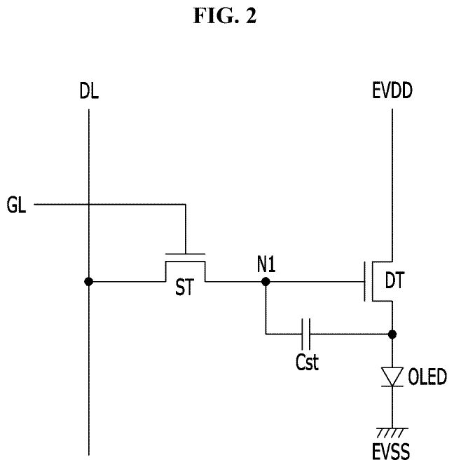

FIG. 1 is a configuration diagram describing a concept of a configuration of a display apparatus according to an embodiment of the invention. FIG. 2 is a circuit diagram describing a pixel equivalent circuit applicable to a display panel according to an embodiment of the invention.

As illustrated in FIG. 1, a display apparatus 1 according to an embodiment of the invention may include a display panel 10, a timing controller 11, a data driver 12, a gate driver 13, and a power supply 20.

In FIG. 1, a case where the timing controller 11, the data driver 12, and the power supply 20 are separately provided is illustrated as an example, but unlike FIG. 1, all or some of the timing controller 11, the data driver 12, and the power supply 20 may be integrated into a drive integrated circuit (IC) in other embodiments. In FIG. 1, the data driver 12, the gate driver 13, and the power supply 20 may configure a panel driving circuit for driving the display panel 10.

As in FIG. 1, the gate driver 13 may be provided in a non-active area NA of the display panel 10, and in this case, the gate driver 13 may be directly formed on a substrate of the display panel 10 in a gate driver in panel (GIP) type. However, the inventive concepts are not limited thereto, and in some embodiments, the gate driver 13 may be mounted on a glass in a chip-on-glass (COG) type or on a flexible film in a chip-on-film (COF) type, etc.

The display panel 10 may include an active area AA and the non-active area NA.

The active area AA may be an area which displays an image. A plurality of subpixels SP may be disposed in the active area AA, and the active area AA may display an image by using the plurality of subpixels SP. An area where the plurality of subpixels SP are disposed may be the active area AA, and the non-active area NA may be an area which is disposed at an outer edge of the display panel 10 to surround the active area AA and does not display an image.

The plurality of subpixels SP is disposed in the active area AA. The plurality of subpixels SP may include a first subpixel SPR emitting first color light, a second subpixel SPG emitting second color light, and a third subpixel SPB emitting third color light. For example, the first color light may be red (R) light, the second color light may be green (G) light, and the third color light may be blue (B) light, and this will be described below as an example.

A plurality of subpixels SP emitting lights of different colors may be grouped into one unit pixel UP. In a case where a pixel group for color expression is defined as a unit pixel UP, the unit pixel UP may be configured to include, for example, a plurality of subpixels SPR, SPG, and SPB respectively emitting red (R) light, green (G) light, and blue (B) light, and moreover, may be configured to further include a subpixel emitting white (W) light, in addition to red (R) light, green (G) light, and blue (B) light. Each unit pixel UP may mix different colors to implement various colors. In embodiments described below, a case where a plurality of subpixels SP emit lights of different colors of red (R) light, green (G) light, and blue (B) light will be described as an example.

In FIG. 1, a case where a unit pixel UP includes a red subpixel SPR emitting red (R) light, a green subpixel SPG emitting green (G) light, and a blue subpixel SPB emitting blue (B) light is illustrated as an example. Hereinafter, a case where a first subpixel is a red subpixel SPR, a second subpixel is a green subpixel SPG, and a third subpixel is a blue subpixel SPB will be described as an example.

At least one panel driving circuit for driving the plurality of subpixels SP may be disposed in the non-active area NA.

The timing controller 11 may receive digital image data D-DATA transferred from a host system (not shown) to supply digital image data D-DATA to the data driver 12.

The timing controller 11 may receive a timing signal such as a vertical synchronization signal, a horizontal synchronization signal, a data enable signal, and a dot clock from the host system to generate timing control signals for controlling an operation timing of the panel driving circuit.

The timing control signals may include a gate timing control signal GDC for controlling an operation timing of the gate driver 13, a data timing control signal DDC for controlling an operation timing of the data driver 12, and a power timing control signal PDC for controlling an operation timing of the power supply 20.

The data driver 12 may be electrically connected to the plurality of subpixels SP through data lines DL (DL1 to DLm). The data driver 12 may generate data voltages, which are analog signals for driving of the plurality of subpixels SP, and may respectively supply the data voltages to the data lines DL, based on the digital image data D-DATA input from the timing controller 11.

The data driver 12 may sample and latch the digital image data D-DATA input from the timing controller 11 to generate parallel data, based on the data timing control signal DDC.

Subsequently, the data driver 12 may convert the digital image data D-DATA into analog data voltages Vdata by using a digital-to-analog converter (DAC), based on gamma compensation voltages, and may respectively supply the analog data voltages to the plurality of subpixels SP through the data lines DL. The analog data voltages may be analog voltage values of different voltage levels to correspond to image gray levels which are to be expressed in the plurality of subpixels SP.

The data driver 12 may output the data voltages to the plurality of subpixels SP, based on the data timing control signal DDC. The data driver 12 may include a plurality of source driver integrated circuits (ICs). Each of the source driver ICs may include a shift register, a latch, a level shifter, the DAC, and an output buffer.

The gate driver 13 may generate scan signals SC to supply the scan signals SC to the plurality of subpixels SP through gate lines GL (GL1 to GLn), based on the gate timing control signal GDC.

The power supply 20 may process an input power to generate a level-fixed high-level driving voltage EVDD and may supply the high-level driving voltage EVDD to the display panel, based on the power timing control signal PDC.

As illustrated in FIG. 2, for example, at least one of the plurality of subpixels SP may include a switching transistor ST, a driving transistor DT, a capacitor Cst, and a light emitting device OLED.

A first electrode of the switching transistor ST may be electrically connected to a data line DL to receive a data voltage, a second electrode thereof may be electrically connected to a first node N1, and a gate electrode of the switching transistor ST may be electrically connected to a gate line GL to receive a scan signal. The switching transistor ST may transfer a data voltage, supplied through the data line DL, to the first node N1 in response to the scan signal supplied through the gate line GL.

A first electrode of the driving transistor DT may be supplied with a high-level driving voltage EVDD, and a second electrode thereof may be electrically connected to a first electrode of the light emitting device OLED. The driving transistor DT may generate a driving current Id flowing in the light emitting device OLED in response to a voltage applied from the first node N1 to a gate electrode thereof.

One end of the capacitor Cst may be electrically connected to the first node N1, the other end thereof may be electrically connected to the second electrode of the driving transistor DT, and the capacitor Cst may be charged with a voltage applied to the first node N1.

The light emitting device OLED may output light corresponding to the driving current Id. The light emitting device OLED may emit light corresponding to one color among red (R), green (G), blue (B), and white (W).

For example, the light emitting device OLED may include an emission layer which generates light having one color. The emission layer may be implemented to emit light of a different color for each subpixel SP as in light of white (W), red (R), green (G), or blue (B).

Moreover, although not shown in FIG. 2, a compensation circuit (not shown) for compensating for a threshold voltage of the driving transistor DT may be further included in the subpixel SP. The compensation circuit may include at least one transistor connected to the driving transistor DT and may be provided in the subpixel SP.

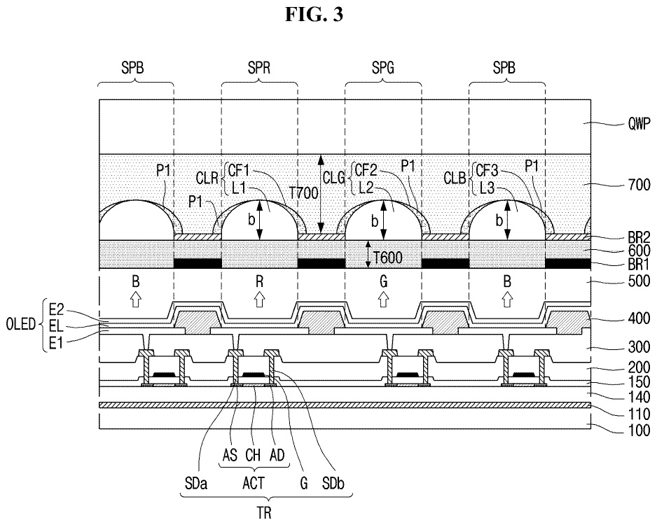

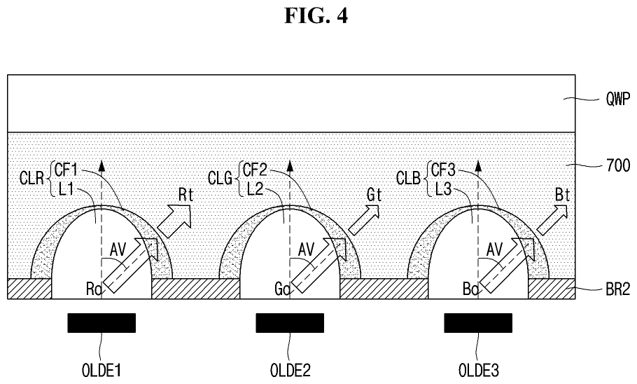

FIG. 3 is a cross-sectional view describing a structure of a display panel 10 according to an embodiment of the invention, and FIG. 4 is a diagram describing functions of first to third color filter layers illustrated in FIG. 3.

As illustrated in FIG. 3, the display panel 10 may include a substrate 100, an insulation layer 110, a buffer layer 140, a gate insulation layer 150, an interlayer insulation layer 200, a planarization layer 300, a bank 400, a light emitting device OLED, an encapsulation layer 500, a first barrier BR1, an optical layer 600, a second barrier BR2, a plurality of color filter lenses CLR, CLG, and CLB, a low refractive layer 700, and a quarter wave plate QWP.

In FIG. 3, a transistor TR may be one of a switching transistor ST and a driving transistor DT, and a case where the transistor TR is the driving transistor DT illustrated in FIG. 2 is illustrated as an example. A cross-sectional structure of the display apparatus illustrated in FIG. 3 may be an embodiment for understanding the invention, and embodiments of the invention are not limited thereto.

The substrate 100 may include a flexible plastic material to exhibit a flexible characteristic, and moreover, may include a flexible glass material with a thin thickness, without being limited thereto.

The insulation layer 110 may be disposed in an active area AA and a non-active area NA of the substrate 100. The insulation layer 110 may be disposed on the substrate 100 and may protect structures on the substrate 100 vulnerable to the penetration of water through the substrate 100. The insulation layer 110 may include one or more inorganic layers among silicon oxide (SiOx), silicon nitride (SiNx) and silicon oxynitride (SiOxNy), without being limited thereto.

The buffer layer 140 may be disposed on the insulation layer 110. The buffer layer 140 may include an inorganic insulating material such as SiOx or SiNx, without being limited thereto.

The transistor TR may be disposed on the buffer layer 140. The transistor TR may include a gate electrode G, an active layer ACT, a source electrode SDa, and a drain electrode SDb.

The active layer ACT may include a source region AS, a channel region CH, and a drain region AD. The source region AS and the drain region AD may have an electrical conductance which is higher than that of the channel region CH, and the channel region CH may form a channel in response to a voltage applied to a gate electrode.

The gate insulation layer 150 may be stacked on the buffer layer 140 while covering the active layer ACT. The gate insulation layer 150 may insulate a gate electrode G of the transistor TR from the active layer ACT.

The interlayer insulation layer 200 may be disposed on the gate insulation layer 150 to cover the gate electrode G of the transistor TR. The source electrode SDa and the drain electrode SDb of the transistor TR may be disposed on the interlayer insulation layer 200.

The source electrode SDa and the drain electrode SDb may pass through the interlayer insulation layer 200 and the gate insulation layer 150 and may contact the source region AS and the drain region AD of the transistor TR.

The planarization layer 300 may be stacked on the interlayer insulation layer 200 to cover the source electrode SDa and the drain electrode SDb of the transistor TR. The planarization layer 300 may remove a step height caused by a driving circuit, and an upper surface thereof may include a flat surface. The planarization layer 300 may include an insulating material having high flexibility.

One of the source electrode SDa and the drain electrode SDb of the transistor TR may pass through the planarization layer 300 and may contact a first electrode E1 of the light emitting device OLED.

The bank 400 may be disposed on the planarization layer 300. The bank 400 may define an emission region of each subpixel, and a region of each subpixel may be divided by the bank 400.

The bank 400 may include a light-absorbing material, and for example, may include a black pigment such as carbon black, without being limited thereto. Accordingly, the bank 400 may absorb external light, and thus, may minimize a light reflection rate, further enhance a black color, and improve a contrast ratio and color accuracy, thereby further improving image quality.

The bank 400 may include an organic insulating material. The bank 400 may cover an edge of the first electrode E1 (for example, an anode electrode). An emission layer EL and a second electrode E2 (for example, a cathode electrode) may be stacked on a partial region of the first electrode E1 exposed by the bank 400.

Therefore, an emission region of each of a plurality of subpixels SPR, SPG, and SPB may be divided by the bank 400. The emission region of each of the plurality of subpixels SPR, SPG, and SPB may be a region where the first electrode E1 is exposed by the bank 400.

The light emitting device OLED may be disposed in the emission region and may include the first electrode E1, the emission layer EL, and the second electrode E2. The bank 400 may be disposed to at least partially overlap a space between two adjacent color filter lenses among first to third color filter lenses CLR, CLG, and CLB.

The first electrode E1, for example, may function as an anode electrode and may include a conductive material. The first electrode E1 may have a high reflectance. For example, the first electrode E1 may include metal such as aluminum (Al) and silver (Ag), without being limited thereto. The first electrode E1 may be exposed at the emission region of each subpixel by the bank 400.

The emission layer EL may generate colored light having luminance that corresponds to a voltage difference between the first electrode E1 and the second electrode E2. For example, an emission layer EL included in a first subpixel SPR may generate red light R which is first color light R, an emission layer EL included in a second subpixel SPG may generate green light G which is second color light G, and an emission layer EL included in a third subpixel SPB may generate blue light B which is third color light B.

The emission layer EL may include an emission material layer (EML) including an emission material. The emission material may include an organic material, an inorganic material, or a hybrid material, without being limited thereto. For example, the emission layer EL may include an emission material layer including an organic material.

The emission layer EL may include at least one of a first emission common layer (not shown) disposed between first electrodes E1 and a second emission common layer (not shown) disposed between second electrodes E2. Each of the first emission common layer (not shown) and the second emission common layer (not shown) may include at least one of a hole transport layer (HTL) and an electron transport layer (ETL).

The emission layer EL may be electrically connected to the first to third subpixels SPR, SPG, and SPB. For example, the emission material layer EML of each subpixel may be provided for each subpixel, but the first and second emission common layers (not shown) may be electrically connected to the first to third subpixels SPR, SPG, and SPB in common.

Therefore, an emission layer EL of a first light emitting device OLED1 (OLED) included in the first subpixel SPR may be electrically connected to an emission layer EL of a second light emitting device OLED2 (OLED) included in the second subpixel SPG.

The second electrode E2, for example, may function as a cathode electrode and may include a conductive material. The second electrode E2 may include a material which differs from that of the first electrode E1. For example, the second electrode E2 may be a transparent electrode including a conductive material such as indium tin oxide (ITO) and indium zinc oxide (IZO), without being limited thereto. The second electrode E2 may have a transmittance which is higher than that of the first electrode E1.

The encapsulation layer 500 may be disposed on the second electrode E2 on the emission layer EL and may perform an encapsulation function of preventing light emitting devices OLED from being damaged by an external impact or water.

The encapsulation layer 500 may include an inorganic insulation material layer and an organic insulation material layer, which are alternately stacked. A step height caused by the light emitting device OLED may be removed by the encapsulation layer 500, and an upper surface of the encapsulation layer 500 may be a flat surface.

The optical layer 600 may be disposed on the encapsulation layer 500. The optical layer 600 may form an upper surface and may thus function as an optical gap which induces uniform light refraction, thereby enhancing light extraction efficiency.

The optical layer 600 may have a refractive index which is lower than that of each of the plurality of color filter lenses CLR, CLG, and CLB, and a thickness T600 of the optical layer 600 may be less than a maximum height “b” of each of the first to third color filter lenses CLR, CLG, and CLB. The optical layer 600 may include polyimide-acrylic composite (PAC).

The first barrier BR1 may be disposed at a portion at least partially overlapping the bank 400, between the encapsulation layer 500 and the optical layer 600. The first barrier BR1 may prevent mixing of colors caused by color light emitted from a light emitting device OLED of an adjacent subpixel. For example, the first barrier BR1 may be formed of a black matrix including a black pigment which is a light-absorbing material.

The second barrier BR2 may be disposed at a portion at least partially overlapping the bank 400, between the optical layer 600 and the low refractive layer 700. An edge of the second barrier BR2 may at least partially overlap edges of the first to third color filter lenses CLR, CLG, and CLB.

The second barrier BR2 may prevent mixing of colors caused by color light emitted from a light emitting device OLED of an adjacent subpixel along with the first barrier BR1. The second barrier BR2 may be a touch electrode of an opaque metal material. The second barrier BR2 may be one of a touch driving electrode and a touch receiving electrode.

As described above, the first and second barriers BR1 and BR2 may prevent color lights of adjacent subpixels from being inadvertently mixed and collected in a color filter lens of a corresponding subpixel, and may block a viewing angle such that color light emitted from each subpixel does not obstruct a field of view of a driver.

The plurality of color filter lenses CLR, CLG, and CLB may be disposed at a portion at least partially overlapping an emission region of each subpixel, on the optical layer 600. For example, one first color filter lens CLR may be disposed to at least partially overlap an emission region of the first subpixel SPR, one second color filter lens CLG may be disposed to at least partially overlap an emission region of the second subpixel SPG, and one third color filter lens CLB may be disposed to at least partially overlap an emission region of the third subpixel SPB. In an embodiment, only one first color filter lens CLR may be disposed to at least partially overlap an emission region of the first subpixel SPR, only one second color filter lens CLG may be disposed to at least partially overlap an emission region of the second subpixel SPG, and only one third color filter lens CLB may be disposed to at least partially overlap an emission region of the third subpixel SPB

A refractive index of each of the first to third color filter lenses CLR, CLG, and CLB may be greater than that of the low refractive layer 700, and may collect and output color light emitted from a corresponding subpixel among the first to third subpixels SPR, SPG, and SPB, thereby enhancing a front luminance of the display panel.

The first to third color filter lenses CLR, CLG, and CLB may respectively include first to third lenses L1 to L3 and first to third color filter layers CF1 to CF3.

Each of the first to third lenses L1 to L3 may be disposed to at least partially overlap a corresponding subpixel among the first to third subpixels SPR, SPG, and SPB, and may collect color light emitted from a corresponding subpixel to enhance luminance.

Each of the first to third lenses L1 to L3 may not include a colored pigment and may include a transparent lens material. The lens material may include at least one of a polymer-based material and an inorganic material. For example, the polymer-based material may include at least one of polymethyl methacrylate (PMMA), polyimide, and epoxy resin, and the inorganic material may include at least one of silica (SiO₂) and titania (TiO₂), and in addition thereto, the lens material may include a polymer-inorganic composite, without being limited thereto.

The first to third color filter layers CF1 to CF3 may be respectively disposed on surfaces of the first to third lenses L1 to L3. An outer surface of each of the first to third color filter layers CF1 to CF3 may include a curved surface corresponding to an upper curved surface of a corresponding lens among the first to third lenses L1 to L3. A curved surface based on a curved surface of each of the first to third lenses L1 to L3 may be provided outside a corresponding color filter layer among the first to third color filter layers CF1 to CF3.

The first color filter layer CF1 may include a pigment which transmits the first color light R, the second color filter layer CF2 may include a pigment which transmits the second color light G, and the third color filter layer CF3 may include a pigment which transmits the third color light B.

Transmittances of color filter layers may differ, based on pigments included in the first to third color filter layers CF1 to CF3. In detail, a transmittance of the second color light G of the second color filter layer CF2 may be lower than that of the first color light R of the first color filter layer CF1, and a transmittance of the third color light B of the third color filter layer CF3 may be lower than that of the first color light R of the first color filter layer CF1.

For example, as illustrated in FIG. 4, second color light Go emitted from the second light emitting device OLED2 emitting the green light G, and third color light Bo emitted from an optical axis of the third light emitting device OLED3 emitting the blue light B, may each be emitted at a viewing angle AV with respect to their respective optical axes and output through the second lens L2 and the third lens L3. When the second color light Go and the third color light Bo pass through the second and third color filter layers CF2 and CF3, respectively, the transmitted second and third color lights Gt and Bt may have reduced brightness compared to the output second and third color lights Go and Bo. More particularly, the brightness of the green light G and the blue light B may be reduced by the second and third color filter layers CF2 and CF3.

However, as illustrated in FIG. 4, when first color light Ro, which is emitted with a specific viewing angle AV from an optical axis of the first light emitting device OLED1 emitting the red light R and is output through the first lens L1, passes through the first color filter layer CF1, the transmitted first color light Rt may maintain brightness of output first color light Ro. More particularly, the brightness of the red light R may be maintained without being reduced, based on the first color filter layer CF1.

Pigments included in the first to third color filter layers CF1 to CF3 may be the same first pigment P1. A reduction rate of brightness of the second and third color lights G and B caused by the first pigment P1 may be greater than a reduction rate of brightness of the first color light R caused by the first pigment P1. For example, brightness of the first color light R may be maintained by the first pigment P1, and brightness of the second and third color lights G and B may be reduced by the first pigment P1.

A transmittance of the first pigment P1 on the green light G and the blue light B may be lower than a transmittance of the first pigment P1 on the red light R. Based on a per-color transmittance difference of the first pigment P1, for example, the first color filter layer CF1 may maintain brightness of the first color light R, and the second and third color filter layers CF2 and CF3 may reduce brightness of the second and third color lights G and B.

For example, the first pigment P1 may include at least one of chlorinated copper phthalocyanine (PG7), PG36, and nickel complex pigments which are pigments for green color filter, and copper phthalocyanine (PB15:3), indanthrone blue (PB60), and ultramarine blue which are pigments for blue color filter.

Moreover, the first to third color filter layers CF1 to CF3 may further include a binding polymer for color filter and a dispersion stabilizer which helps film formation and the uniform dispersion of pigment particles.

The binding polymer for color filter may include at least one of epoxy resin (for example, cycloaliphatic epoxy resin and novolac epoxy resin), acrylic resin (for example, poly methyl methacrylate and cross-linked acrylic polymers), polyimide (for example, fluorinated polyimide), polyurethane (for example, thermosetting polyurethane), without being limited thereto.

The dispersion stabilizer which helps film formation and the uniform dispersion of pigment particles may be hyperdispersants, polyvinyl pyrrolidone, silicone-based surfactants, or other additives, without being limited thereto, and may include at least one of ultraviolet (UV) stabilizers and cross-linking agents.

Each of the first to third color filter layers CF1 to CF3 may further include a lens material by means of mixing, in addition to the first pigment P1, the binding polymer, and the dispersion stabilizer.

Therefore, according to embodiments of the invention, a refractive index of each of the first to third color filter layers CF1 to CF3 may be substantially the same as that of each of the first to third lenses L1 to L3. As described above, a refractive index of a color filter layer may be substantially the same as that of a lens, and thus, the reflection or refraction of color light from an interface between the color filter layer and the lens may be minimized.

Color filter layers may not use different pigments and may use one first pigment in common, and thus, may decrease the cost and manufacturing process of a color filter layer.

Hereinabove, an example where the first to third color filter layers CF1 to CF3 include the same first pigment P1 has been described, but embodiments of the invention are not limited thereto. For example, pigments included in the first to third color filter layers CF1 to CF3 may be different in other embodiments. Hereinafter, for convenience of description, a case where pigments included in the first to third color filter layers CF1 to CF3 are substantially the same first pigment P1 will be described as an example.

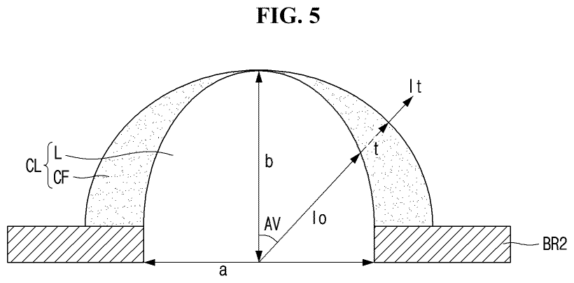

Thicknesses of the first to third color filter layers CF1 to CF3 in side surfaces of the first to third lenses L1 to L3 may be greater than thicknesses of the first to third color filter layers CF1 to CF3 in centers of upper surfaces of the first to third lenses L1 to L3, respectively. This will be described below with reference to FIG. 5.

The low refractive layer 700 may be disposed on the first to third color filter lenses CLR, CLG, and CLB and the second barrier BR2 exposed at a region between adjacent color filter lenses. A refractive index of the low refractive layer 700 may be lower than that of each of the first to third color filter lenses CLR, CLG, and CLB.

The low refractive layer 700 may remove a step height caused by each color filter lens, and an upper surface thereof may include a flat surface. The low refractive layer 700 may include an insulating material having high flexibility. A thickness T700 of the low refractive layer 700 may be greater than a maximum height “b” of each of the first to third color filter lenses CLR, CLG, and CLB.

The quarter wave plate QWP may be disposed on the low refractive layer 700 and may phase-delay, by λ/4, a wavelength of color light of each subpixel passing through the first to third color filter lenses CLR, CLG, and CLB. The quarter wave plate QWP may convert linear polarization into circular polarization and may convert circular polarization into linear polarization. The quarter wave plate QWP may be provided along with a polarizer (not shown) and may be used to decrease the reflection of external light or increase or decrease a viewing angle of color light of each subpixel.

A cover layer (not shown) such as glass, which protects the quarter wave plate QWP from the outside, may be further provided on the quarter wave plate QWP.

In embodiments of the invention, first to third color filter layers may be provided on surfaces of first to third lenses disposed on first to third subpixels emitting first to third color lights, and light transmittances of the first to third color filter layers may differ for each color light, thereby enhancing the visibility of a display panel.

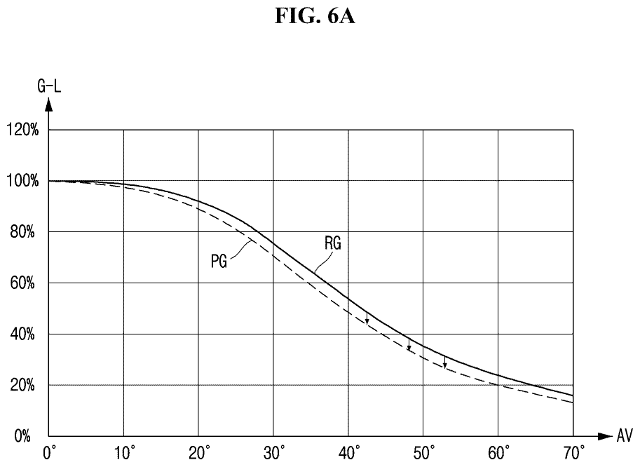

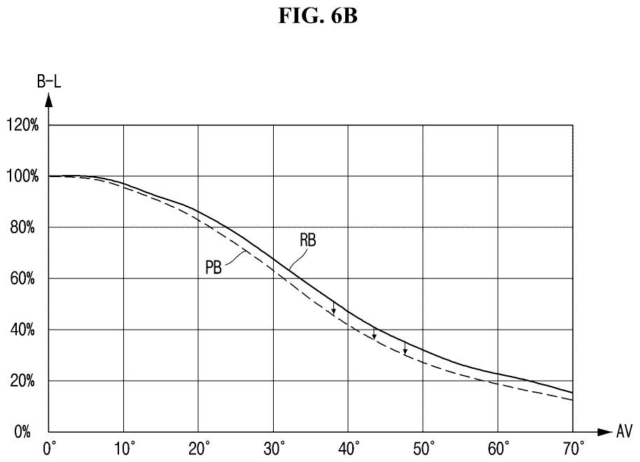

FIG. 5 is an enlarged view for describing a thickness variation of a color filter layer in each color filter lens illustrated in FIG. 3, and FIGS. 6A and 6B are graphs for describing a degree to which brightness of second and third color lights is reduced with respect to a viewing angle, when a color filter layer has a thickness as in FIG. 5.

A color filter layer CF and a thickness “t” of the color filter layer CF illustrated in FIG. 5 may be substantially identically applied to each of the first to third color filter lenses CLR, CLG, and CLB described above.

In FIG. 5, “Io” may denote brightness of color light which is emitted from a light emitting device and is output through a lens L, and “It” may denote brightness of color light passing through the color filter layer CF.

A thickness “t” of the color filter layer CF at a side surface of the lens L may be greater than a thickness “t” of the color filter layer CF at a center of an upper surface of the lens L. For example, as illustrated in FIG. 5, the thickness “t” of the color filter layer CF may increase progressively toward the side surface of the lens L from the center of the upper surface of the lens L. For example, the thickness “t” of the color filter layer CF may increase as expressed in the following Equation 1.

$$[ Equation 1 ]$$

$$t = \sqrt{{( \frac{ab}{{b}^{2} + {a}^{2} / {tan}^{2} θ} - b sin θ )}^{2} + {( \frac{ab}{{b}^{2} tan θ + {a}^{2} / tan θ} - b cos θ )}^{2}}$$

Here, “a” may denote a maximum width of the lens L, “b” may denote a maximum height of the lens L, 0 may denote an output angle or a viewing angle of color light inclined from an optical axis which is a front of a light emitting device, and “t” may denote a thickness of the color filter layer CF.

Therefore, a brightness reduction rate of each of the second and third color lights G and B caused by the second and third color filter layers CF2 and CF3 may be greater at a second viewing angle than at a first viewing angle which corresponds to a front of each of the second and third light emitting devices OLED2 and OLED3. The second viewing angle may be different from the first viewing angle.

In detail, in the second and third color filter lenses CLG and CLB, when a viewing angle is a front of a light emitting device, a transmittance and brightness of each of the second and third color lights G and B may be hardly reduced by the second and third color filter layers CF2 and CF3. However, when a viewing angle increases, a degree to which a transmittance and brightness of each of the second and third color lights G and B are reduced may be relatively further increased than a case where a color filter layer is omitted.

Furthermore, in the first color filter lens CLR, a degree to which a transmittance and brightness of the first color light R are reduced by the first color filter layer CF1 may be substantially the same as a case where a color filter layer is omitted, regardless of an increase or a decrease in a viewing angle.

According to embodiments of the invention, when a thickness of each of the first to third color filter layers CF1 to CF3 varies, as illustrated in FIGS. 6A and 6B, a degree to which brightness of the second and third color lights G and B is reduced with respect to a viewing angle may be changed.

FIG. 6A is a graph describing a degree to which brightness of second color light is reduced with respect to a viewing angle of a second color filter lens according to an embodiment PG, compared to a comparative example RG, and FIG. 6B is a graph describing a degree to which brightness of third color light is reduced with respect to a viewing angle of a third color filter lens according to an embodiment PB, compared to a comparative example RB.

The comparative example RG of FIG. 6A may correspond to a case where a second color filter layer is omitted in a second color filter lens, and the entire second color filter lens is configured with only a transparent lens, and the comparative example RB of FIG. 6B may correspond to a case where a third color filter layer is omitted in a third color filter lens, and the entire third color filter lens is configured with only a transparent lens.

In FIGS. 6A and 6B, an x axis may denote a viewing angle, and a y axis may denote brightness of color light with respect to a viewing angle.

In FIGS. 6A and 6B, in all of the embodiments PG and PB and the comparative examples RG and RB, it may be seen that brightness G-L of second color light G and brightness B-L of third color light B are reduced as a viewing angle increases, with respect to a front viewing angle (for example, 0 degrees (0°)).

However, as a viewing angle increases, the brightness G-L of the second color light G according to the embodiment PG and the brightness B-L of the third color light B according to the embodiment PB may be reduced to a greater extent than the comparative examples RG and RB.

In detail, as illustrated in FIGS. 6A and 6B, in all of the embodiments PG and PB and the comparative examples RG and RB, when a viewing angle is 0 degrees, the brightness G-L of the second color light G and the brightness B-L of the third color light B may not be reduced and may all substantially be equal to be 100%. However, when the viewing angle AV has a large angle of 20 degrees or more, the brightness G-L of the second color light G according to the embodiment PG and the brightness B-L of the third color light B according to the embodiment PB may be relatively more reduced than the comparative examples RG and RB.

Although not illustrated in FIGS. 6A and 6B, in terms of the degree to which a first color R is reduced with respect to a viewing angle AV, a first color filter lens CLR according to an embodiment of the invention may be substantially the same as a comparative example.

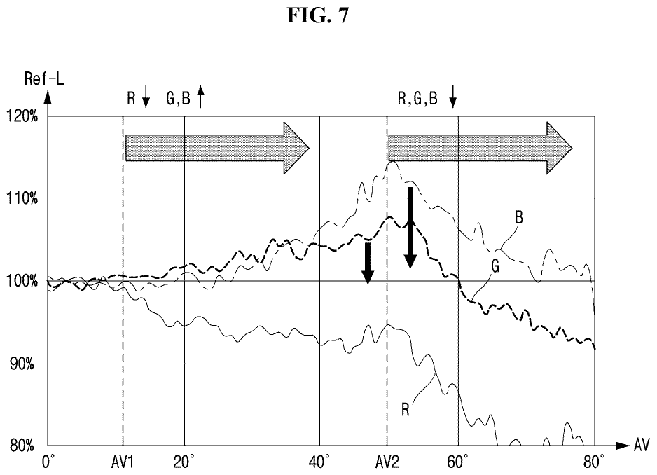

Hereinafter, in a comparative example, brightness variations of first to third color lights with respect to a viewing angle will be described with reference to FIG. 7.

FIG. 7 is a graph for describing brightness variations of first to third color lights R, G, and B with respect to a viewing angle when a lens disposed on a subpixel is configured with only a transparent lens without a color filter layer.

Hereinafter, for convenience of description, a state where a lens L is not provided on a subpixel may denote a reference value, and a state where a whole color filter lens includes only a lens L without a color filter layer may denote a comparative example.

In FIG. 7, an x axis may denote a viewing angle, and a y axis may denote that a brightness ratio Ref-L of color light of a comparative example to a reference value with respect to a viewing angle represents a percentage (%). The y axis may represent a degree of brightness of color light according to a comparative example with respect to a reference value, when brightness of color light of each reference value with respect to a viewing angle is set to 100.

As illustrated in FIG. 7, when a viewing angle is about 10 degrees or less and is close to the front of a subpixel, brightness of color light to a reference value may be about 100%, in all of first to third color lights R, G, and B. In brightness of color light in the front, it may be seen that a reference value is almost equal to the comparative example.

However, when a viewing angle increases from AV1 to AV2, it may be confirmed that, in the first color light R, a brightness ratio Ref-L of color light to a reference value may decrease by about 95%, but in the second color light G, a brightness ratio Ref-L of color light to a reference value may increase up to about 105%, and in the third color light B, a brightness ratio Ref-L of color light to a reference value may increase up to about 115%.

Moreover, when a viewing angle increases to AV2 or more, in all of the first to third color lights R, G, and B, a brightness ratio Ref-L of color light to a reference value may decrease.

More particularly, in the comparative example, a difference between a brightness ratio Ref-L of first color light R and a brightness ratio Ref-L of each of second and third color lights G and B to a reference value may increase overall while a viewing angle is increasing from AV1 to AV2, and when a viewing angle increases to AV2 or more, a brightness ratio Ref-L difference between the first color light R and the second and third color lights G and B may be maintained.

As described above, in a comparative example where only a lens L is provided on a subpixel, as a viewing angle increases, a difference of a brightness variation with respect to color light may increase, and thus, a brightness ratio variation with respect to color light is changed, and due to this, visibility is reduced. In this case, there may be a problem where color coordinates should be re-set based on a reference value.

However, as described above with reference to FIG. 5 according to embodiments of the invention, when a thickness “t” of a color filter layer CF is formed to be larger at a side surface of the lens L than at a center of an upper surface of the lens L, in FIG. 7, a brightness ratio Ref-L difference to a reference value with respect to a viewing angle may be reduced, and thus, a sense of color may be enhanced even without re-setting color coordinates based on a reference value.

As described above, embodiments of the invention may decrease brightness of the second and third color lights G and B in an arrow direction with respect to an increase in a viewing angle in a state where brightness of the first color light R is maintained. Accordingly, a difference between a brightness variation of first color light and a brightness variation of each of second and third color lights may be reduced, and thus, the visibility of a display panel may be further enhanced.

According to embodiments of the invention, first and second color filter layers may be provided on surfaces of first and second lenses disposed on first and second subpixels respectively emitting first color light and second color light, and light transmittances of the first and second color filter layers may differ with respect to color light, thereby enhancing the visibility of a display panel.

Moreover, according to embodiments of the invention, a thickness of a color filter layer at a side surface of a lens may be greater than that of the color filter layer at a center of an upper surface of the lens, and thus, a difference between a brightness variation of first color light and brightness variations of second and third color lights caused by an increase in a viewing angle may be reduced, thereby further enhancing the visibility of a display panel.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display panel comprising:
a first subpixel including a first light emitting device configured to emit first color light;
a second subpixel including a second light emitting device configured to emit second color light;
a first color filter lens including a first lens at least partially overlapping the first subpixel and a first color filter layer disposed on a surface of the first lens; and
a second color filter lens including a second lens at least partially overlapping the second subpixel and a second color filter layer disposed on a surface of the second lens,
wherein the first color filter layer comprises a pigment to transmit the first color light,
the second color filter layer comprises a pigment to transmit the second color light, and
a transmittance of the second color light of the second color filter layer is lower than a transmittance of the first color light of the first color filter layer.

2. The display panel of claim 1, wherein the first color filter layer and the second color filter layer include a first pigment in common.

3. The display panel of claim 2, wherein a reduction rate of brightness of the second color light caused by the first pigment is greater than a reduction rate of brightness of the first color light caused by the first pigment.

4. The display panel of claim 2, wherein each of the first and second lenses comprises a lens material including at least one of a polymer-based material and an inorganic material, and
each of the first and second color filter layers comprises a combination of the first pigment and the lens material.

5. The display panel of claim 2, wherein the first pigment comprises at least one of green color filter pigment and blue color filter pigment, and
the green color filter pigment is selected from at least one of chlorinated copper phthalocyanine (PG7), PG36, and nickel complex pigments, and the blue color filter pigment is selected from at least one of copper phthalocyanine (PB15:3), indanthrone blue (PB60), and ultramarine blue.

6. The display panel of claim 1, wherein an outer surface of each of the first and second color filter layers comprises a curved surface corresponding to an upper curved surface of a corresponding lens among the first and second lenses.

7. The display panel of claim 1, wherein a refractive index of the first color filter layer is substantially the same as a refractive index of the first lens, and
a refractive index of the second color filter layer is substantially the same as a refractive index of the second lens.

8. The display panel of claim 1, wherein a maximum height of each of the first and second lenses is greater than a maximum width of each of the first and second lenses.

9. The display panel of claim 1, wherein a thickness of each of the first and second color filter layers at a side surface of a corresponding lens among the first and second lenses is greater than a thickness of each of the first and second color filter layers at a center of an upper surface of a corresponding lens among the first and second lenses.

10. The display panel of claim 1, wherein a brightness reduction rate of the second color light caused by the second color filter layer is greater at a second viewing angle than at a first viewing angle corresponding to a front of the second light emitting device, the second viewing angle being different from the first viewing angle.

11. The display panel of claim 1, wherein the first color light is red light, and the second color light is green light or blue light.

12. The display panel of claim 1, wherein only one first color filter lens is disposed on the first subpixel, and
only one second color filter lens is disposed on the second subpixel.

13. The display panel of claim 1, further comprising:
an encapsulation layer disposed on the first and second light emitting devices;
an optical layer disposed between the encapsulation layer and the first and second color filter lenses; and
a low refractive layer disposed on the first and second color filter lenses,
wherein a refractive index of each of the first and second color filter lenses is greater than a refractive index of the low refractive layer.

14. The display panel of claim 13, wherein a thickness of the optical layer is less than a maximum height of each of the first and second color filter lenses.

15. The display panel of claim 13, wherein a thickness of the low refractive layer is greater than a maximum height of each of the first and second color filter lenses.

16. The display panel of claim 13, further comprising a bank defining an emission region of the first subpixel and an emission region of the second subpixel,
wherein the bank at least partially overlaps a space between the first color filter lens and the second color filter lens.

17. The display panel of claim 16, further comprising a first barrier at a portion at least partially overlapping the bank, between the encapsulation layer and the optical layer,
wherein the first barrier comprises a black matrix including a light-absorbing material.

18. The display panel of claim 16, further comprising a second barrier at a portion at least partially overlapping the bank, between the optical layer and the low refractive layer,
wherein the second barrier comprises a touch electrode including a metal material.

19. The display panel of claim 1, further comprising:
a third subpixel including a third light emitting device configured to emit third color light;
a third color filter lens including a third lens at least partially overlapping the third subpixel and a third color filter layer disposed on a surface of the third lens,
wherein the third color filter layer comprises a pigment to transmit the third color light, and
a transmittance of the third color light of the third color filter layer is lower than a transmittance of the first color light of the first color filter layer.

20. The display panel of claim 19, wherein a brightness reduction rate of the third color light caused by the third color filter layer is greater at a second viewing angle than at a first viewing angle corresponding to a front of the third light emitting device, the second viewing angle being different from the first viewing angle.
